(19) United States
(12) Patent Application Publication
(10) Pub. No.: US 2007/0186848 A1
(43) Pub. Date: Aug. 16, 2007

(54) Coating system and coating method

(76) Inventors: Francis-Jurjen Ladru, Berlin (DE); Gerhard Reich, Berlin (DE); Michael Riemann, Berlin (DE); Falk Stadelmaier, Berlin (DE)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 11/653,202

(22) Filed: Jan. 12, 2007

(30) Foreign Application Priority Data
Jan. 12, 2006 (EP) 06000641.8

(51) Int. Cl. C23C 14/00; B05C 5/00; B05B 5/025

(52) U.S. Cl. 118/50; 118/300; 118/620

(57) ABSTRACT

The invention relates to a coating system, especially a low pressure plasma coating system, with at least one treatment chamber and a coating tool, especially a plasma spraying device, wherein at least one pump is provided for evacuation of the treatment chamber, which treatment chamber is formed to be temperature controllable. In addition there is a coating method for low pressure plasma coating with a temperature controlled and evacuated treatment chamber, in which a workpiece is coated by means of at least one coating tool. For acceleration of the coating process, especially the evacuating of the treatment chamber, it is proposed that at least the walls of the treatment chamber and/or the inside of the treatment chamber are temperature controlled at a temperature between 45° C. and 75° C.

### CROSS REFERENCE TO RELATED APPLICATIONS

This application claims the benefits of European Patent application No. 06000641.8 filed Jan. 12, 2006. All of the applications are incorporated by reference herein in their entirety.

### FIELD OF INVENTION

The invention relates to a coating system, especially a low pressure plasma coating system, with at least one treatment chamber and a coating tool, especially a plasma spraying device, wherein at least one pump is provided for evacuation of the treatment chamber, which treatment chamber is formed to be temperature controllable. In addition, a coating method with a temperature controlled and evacuated treatment chamber, in which a workpiece is coated by means of at least one coating tool, is the subject of the invention.

### BACKGROUND OF THE INVENTION

Coatings are frequently used to improve the superficial mechanical or chemical properties of a workpiece according to the application purpose. An improvement in this case can lie in the addition of different properties to the actual base material, for example a tooth flank surface of a gearwheel can be provided with a ductile copper coating, or the hot gas corrosion resistance of the surface of a gas turbine blade can be improved. The so-called low pressure plasma coating technique is advantageously used especially for the last mentioned application. The coating technique is confronted in this connection with a constant challenge by means of increasing demands on the service life of the coating under high load. In this case, it is not enough if in some places the coating outlasts certain service lives and in other places the coating is quickly worn out; on the contrary, an outlasting of the coating on the whole coating surface is desired. For this reason, even small impairments of the coating quality are to be avoided; for example an impairment of the adhesion of the coating on account of impurities of the workpiece is to be avoided before or during the coating process. A high degree of cleanliness and a good vacuum in the coating chamber during the coating process are essential, therefore, for a good quality of coating. In addition, a thermal pretreatment of the workpiece which is to be coated is also of high importance; frequently the workpiece is first to be heated to a certain temperature so that the coating material forms a firm bond with the base material. Previous coating methods, for example, provide for a heating of the workpiece preferably in an antechamber of the actual treatment chamber, under a vacuum or under a protective gas atmosphere, and provide for a subsequent coating also under a vacuum or protective gas atmosphere in a treatment chamber, as the case may be. The negative pressures which are achieved by the evacuating vary in this case between 0.1 mbar, at the beginning of the treatment, and 30 mbar, after application of the protective gas atmosphere and during coating. A high-powered pump system requires about 90 seconds for evacuation of a chamber to the desired negative pressure in the case of component parts in the size of a gas turbine blade, for example, which duration has a direct and significant influence on the manufacturing costs of the end product. If this time period is curtailed, it leads to an unacceptably poor quality of the coating, since a too intense absorption of air from the environment during the coating leads either to inadequately adhering chemical structures or to an unwanted chemical change of the coating material. A reason for the long duration of the evacuating process is to be seen inter alia in the unavoidable contamination of the walls of the treatment chambers or antechambers, as the case may be, of such systems. The contaminant layers absorb especially condensates from the moist environmental air in large volumes, which, during the evacuating, evaporate over a long period of time and persistently degrade the quality of the vacuum.

### SUMMARY OF INVENTION

Starting from the problems and disadvantages of the prior art, it has been made the object of the invention to improve the productivity of coating systems, especially low pressure plasma coating systems for coating gas turbine blades, without having to accept losses in the quality of the coating.

The object is achieved according to the invention by means of a coating system or by means of a coating method. The respectively related dependent claims contain advantageous developments of the invention.

A temperature control of the treatment chamber, according to the invention, at a temperature of between 45° C. and 75° C., takes place preferably by means of heat exchangers on the walls of the chamber, which exchange the heat between the chamber walls and a heat transfer fluid, for example water. In the previous prior art, a temperature control of the chamber takes place at a temperature of about 20° C. The increase of the chamber temperature or the temperature of the chamber walls, as the case may be, to 45° C. to 75° C., preferably to 55° C. to 65° C., according to the invention, which produced the best results with regard to the treatment duration and the coating quality, has the great advantage that the desired vacuum can be achieved quicker, and, on account of the high quality of the vacuum, a reduction of the absorption of components of the air from the environment can be very much reduced within the scope of the coating process. Consequently, the quality of the coating is increased, with a simultaneous reduction of the treatment time per workpiece. These positive effects are attributable to the higher temperature of the chamber or the chamber walls, as the case may be, very much reducing the condensation of components of the constantly moist air on the chamber walls or on the contaminants there, as the case may be. If the duration of the evacuation is maintained, a lower pressure can be achieved. On account of the lower volume of condensates in the region of the chamber walls, the negative pressure or the vacuum, as the case may be, is also sustainably stable, since the volume of subsequently evaporating condensates is much reduced on account of the increased temperature.

A further advantage of the increased chamber temperature or chamber wall temperature, as the case may be, results from the workpiece being preheated for the most part to about 900° C. for the purpose of coating, and this temperature should be maintained even during the coating process in the interests of a high coating quality. The increased chamber wall temperature, compared to the prior art, is instrumental in even large workpieces as far as possible maintaining their increased temperature during the coating process. This effect is to be attributed basically to the altered heat balance first of all as a result of heat radiation into the evacuated chambers. As a result of the application of the method according to the invention or the implementation of a coating system according to the invention, as the case may be, the productivity is increased by almost 10%.

The coating system expediently has a second heat exchanger in addition to a first heat exchanger in the region of the chamber walls, which regulates the inlet temperature for the first heat exchanger at 55° C. to 65° C. In the interests of a high throughput of workpieces which are to be coated, it is expedient if the coating system additionally has at least one, preferably two, antechambers in addition to the actual treatment chamber, in which antechambers the workpieces are heated to a temperature of preferably 900° C. which is expedient for the coating. In addition to a temperature control of the antechamber at a temperature of 45° C. to 75° C., it is sensible if the antechambers also experience such a temperature control. In order to carry out the actual coating in a space which is protected as far as possible, it is advantageous if the treatment chamber, in which the coating takes place, is separable from the antechambers in each case by means of a closable partition. Such a lock also enables the maintaining of a high vacuum quality, especially in the treatment chamber. Within the scope of the necessary opening of the partition during the transfer of a workpiece from an antechamber into the treatment chamber, and during the pressure equalization between the treatment chamber and the antechamber which is associated with it, the antechamber can already be evacuated to the level of the treatment chamber so that the treatment chamber, basically without interruption, has the necessary negative pressure for the coating.

For safe operation of the coating tools, as a rule a cooling of the same is necessary by means of a cooling circuit. An energetically especially advantageous balance can be achieved if this cooling circuit exchanges heat with the temperature control circuit for the chambers or the chamber walls, as the case may be, and in this way the energy from the highly exothermal coating process, which for the most part changes into heat, can be used for temperature control of the chambers. A coating method according to the invention proceeds preferably in steps in such a way that an antechamber is evacuated to about 0.1 mbar, the antechamber is flooded with protective gas at a pressure of 30 mbar, which protective gas is preferably argon, then, by means of at least one burner which combusts a mixture of argon with helium or hydrogen, the workpiece is heated to a temperature between 700° C. and 1000° C., preferably 900° C., whereupon the workpiece is transported into the treatment chamber for coating, and by means of the coating tool is provided with the desired coating. Finally, the workpiece is cooled in an antechamber.

### BRIEF DESCRIPTION OF THE DRAWING

In the following, the invention is explained in detail on the basis of a special exemplary embodiment with reference to a drawing. For the person skilled in the art, further embodiments of the invention are apparent in addition to the special exemplary embodiment.

In the drawing:

FIG. 1 shows a schematic view of a coating system according to the invention, and a coating method according to the invention.

### DETAILED DESCRIPTION OF INVENTION

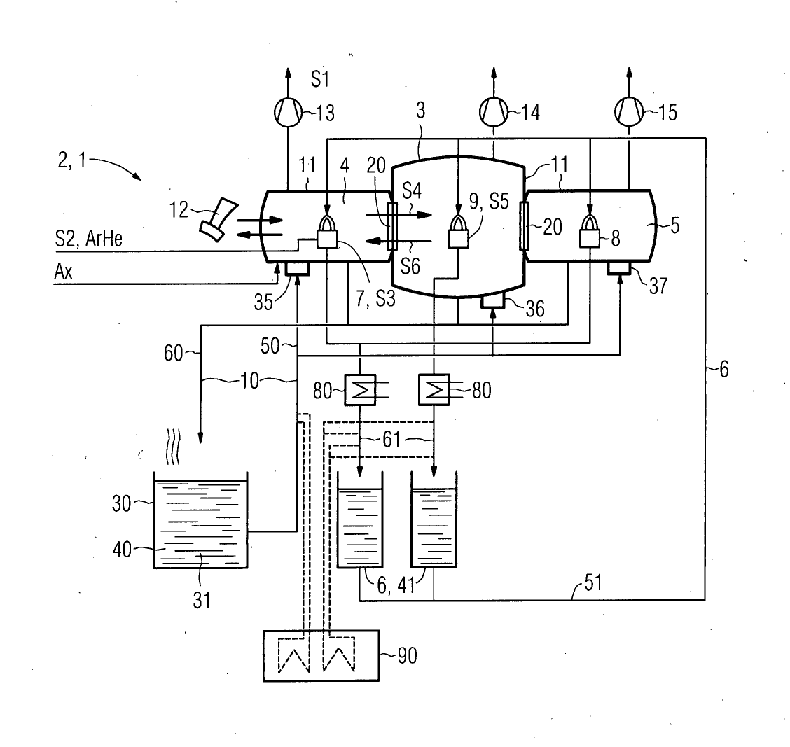

FIG. 1 shows a coating system 1 according to the invention, which is formed as a low pressure plasma coating system 2, and, as essential component parts, has a treatment chamber 3 and two antechambers 4, 5, and also a cooling circuit 6 for cooling of the burners 7, 8 and a coating tool 9, and also a temperature control circuit 10 for temperature control of the antechambers 4, 5 and the treatment chamber 3.

The coating system 1 serves for the coating of workpieces 12, which in a first step S1 are introduced into a first antechamber 4 which is evacuated to a vacuum of 0.1 mbar by means of a first pump 13. Then, the first antechamber 4 is flooded with a protective gas, argon, at a pressure of 30 mbar (second step S2). By means of the first burner 7, the workpiece 12 is heated to a temperature of 900° C. by combustion of an argon-helium mixture (third step S3). In a fourth step S4, a transporting of the workpiece 12 into the treatment chamber 3 takes place, wherein first of all a pressure compensation between the antechamber 4 and the treatment chamber 3 is carried out, and a closable partition 20 between the antechambers 4, 5 and the treatment chamber 3 is temporarily opened. During the fifth step S5, the actual coating of the workpiece 12 takes place by means of the coating tool 9, wherein a second pump 14 constantly keeps the negative pressure of the treatment chamber 3 at about 30 mbar. Finally, the workpiece 12, after a change from the treatment chamber 3 into the first antechamber 4 by opening of the partition 20 in the first antechamber 4, is cooled to an intermediate temperature (sixth step S6). The same process takes place in combination of the treatment chamber 3 with the second antechamber 5.

According to the invention, the antechambers 4, 5 and the treatment chamber 3 or the walls 11 of these chambers, as the case may be, are maintained at a temperature between 55° C. and 65° C. by means of the temperature control circuit 10. The temperature control circuit 10 comprises a tank 30, in which a fluid 31, specifically water, is held for temperature control. The fluid 31 in the tank 30 has a temperature of 55° C. to 65° C. which corresponds to the temperature of the chambers or to the feed temperature of the fluid 31 to first heat exchangers 35, 36, 37, as the case may be. In this case, the tank 30 operates simultaneously as a second heat exchanger 40, which discharges the process heat, which is absorbed by the fluid 31, into the environment. In addition to the temperature control circuit 10, which comprises a chamber water feed line 50 and a chamber water return line 60, the cooling circuit 6 is provided for cooling the burners 7, 8 and the coating tool 9, which cooling circuit has another water tank 41 for the burner, in addition to a burner feed line 51 and a burner return line 61. The burner water tank 41 or the burner feed line 51, as the case may be, preferably has a temperature of 18° C. to 20° C. A cooler 80 in the burner water return line 61 ensures the constancy of this temperature. A heat exchange can optionally take place between the burner water return line 61 and the temperature control circuit 10, preferably to the chamber water feed line 50, by means of a third heat exchanger 90, so that the waste heat from the coating process or from the heating of the workpieces 12, as the case may be, is energetically favorably beneficial to the temperature control of the chambers 3, 4, 5.

1.-8. (canceled)

9. A low pressure plasma coating system, comprising:
a treatment chamber having a plurality of temperature controllable walls that are controlled between 45° C. and 75° C., where a workpiece is treated;
a coating tool arranged in the treatment chamber for coating the workpiece;
a pump connected to the treatment chamber for an evacuation of a chamber atmosphere; and
an antechamber arranged adjacent to the treatment chamber for a thermal pretreatment of the workpiece.

10. The coating system as claimed in claim 9, wherein an interior volume of the treatment chamber is temperature controllable between 45° C. and 75° C.

11. The coating system as claimed in claim 9, further comprising a first heat exchanger that exchanges heat between the treatment chamber and a fluid of a temperature control circuit for temperature control of the treatment chamber.

12. The coating system as claimed in claim 11, further comprising a second heat exchanger that regulates a temperature of the fluid at the header of the first heat exchanger between 55° C. and 65° C.

13. The coating system as claimed in claim 12, wherein a plurality of walls of the antechamber are temperature controlled between 45° C. and 75° C.

14. The coating system as claimed in claim 13, wherein a closable partition is provided between the antechamber and the treatment chamber.

15. The coating system as claimed in claim 14, wherein the coating tool is cooled by a cooling circuit that exchanges heat with a temperature control circuit.

16. A coating method for low pressure plasma coating with a temperature controlled treatment chamber, comprising:
arranging a workpiece in the treatment chamber;
evacuating the atmosphere in the treatment chamber;
controlling an interior temperature of the treating chamber between 45° C. and 75° C.; and
coating the workpiece by a coating tool arranged in the treatment chamber.

17. The coating method as claimed in claim 16, further comprising:
evacuating an antechamber to 0.1 mbar,
filling the antechamber with a protective gas at a pressure of 30 mbar,
heating a workpiece in the antechamber to a temperature between 700° C. and 1000° C. by a heat producing burner,
transporting the workpiece from the antechamber to the treatment chamber,
coating the workpiece by the coating tool, and
cooling the workpiece to produce a coated part.
